(19) United States
(12) Patent Application Publication
(10) Pub. No.: US 2017/0162416 A1
(43) Pub. Date: Jun. 8, 2017

(54) ELECTROSTATIC CHUCK AND SEMICONDUCTOR MANUFACTURING APPARATUS

(71) Applicant: Shinko Electric Industries Co., LTD., Nagano-Ken (JP)

(72) Inventors: Masakuni Miyazawa, Nagano-Ken (JP); Kazuyoshi Miyamoto, Nagano-Ken (JP); Kazunori Shimizu, Nagano-Ken (JP)

(73) Assignee: Shinko Electric Industries Co., LTD., Nagano-Ken (JP)

(21) Appl. No.: 15/347,842

(22) Filed: Nov. 10, 2016

(30) Foreign Application Priority Data
Dec. 3, 2015 (JP) 2015-236642

(51) Int. Cl. H01L 21/683; H01J 37/32; H01L 21/67

(52) U.S. Cl. CPC H01L 21/6833; H01L 21/67069; H01J 37/32715; H01J 2237/3321

(57) ABSTRACT

An electrostatic chuck includes a mount base. The mount base includes a base body and an electrostatic electrode, which is located in the base body. The base body is formed from a ceramic that contains aluminum oxide, which serves as a main component, yttrium oxide, magnesium oxide, and calcium oxide. A content percentage of the calcium oxide is 0.4 wt % to 0.6 wt %.

### CROSS-REFERENCE TO RELATED APPLICATIONS

This application is based upon and claims the benefit of priority from prior Japanese Patent Application No. 2015-236642, filed on Dec. 3, 2015, the entire contents of which are incorporated herein by reference.

### FIELD

This disclosure relates to an electrostatic chuck and an apparatus for manufacturing a semiconductor.

### BACKGROUND

A semiconductor manufacturing apparatus that processes a substrate such as a semiconductor wafer includes an electrostatic chuck, which holds the semiconductor wafer. Japanese Laid-Open Patent Publication Nos. 2008-47885, 2009-238949, and 2014-220408 disclose examples of electrostatic chucks. Examples of the semiconductor manufacturing apparatus include a film formation apparatus such as a CVD apparatus or a PVD apparatus and a plasma etching apparatus. The electrostatic chuck includes a ceramic mount base and an electrostatic electrode, which is located in the mount base. The electrostatic chuck holds a substrate placed on the mount base.

### SUMMARY

In the manufacturing step, the substrate, which is the subject of processing, is attached to the electrostatic chuck in a removable manner. The processing speed in the manufacturing step is affected by the time taken to remove the substrate from the electrostatic chuck (removal operation). Thus, it is desirable that the substrate be quickly removed from the electrostatic chuck.

One embodiment of this disclosure is an electrostatic chuck. The electrostatic chuck includes a mount base including a base body and an electrostatic electrode. The electrostatic electrode is located in the base body. The base body is formed from a ceramic that contains aluminum oxide, which serves as a main component, yttrium oxide, magnesium oxide, and calcium oxide. A content percentage of the calcium oxide is 0.4 wt % to 0.6 wt %.

Another embodiment of this disclosure is a semiconductor manufacturing apparatus. The semiconductor manufacturing apparatus includes a chamber and an electrostatic chuck located in the chamber. The electrostatic chuck includes a mount base on which a substrate to be processed in the chamber is mounted. The mount base includes a base body and an electrostatic electrode located in the base body. The base body is formed from a ceramic that contains aluminum oxide, which serves as a main component, yttrium oxide, magnesium oxide, and calcium oxide. A content percentage of the calcium oxide is 0.4 wt % to 0.6 wt %.

Other embodiments and advantages thereof will become apparent from the following description, taken in conjunction with the accompanying drawings, illustrating by way of example the principles of this disclosure.

It is to be understood that both the foregoing general description and the following detailed description are exemplary and explanatory and are not restrictive of the invention, as claimed.

### BRIEF DESCRIPTION OF THE DRAWINGS

The embodiments, together with objects and advantages thereof, may best be understood by reference to the following description of the presently preferred embodiments together with the accompanying drawings in which:

FIG. 1 is a schematic cross-sectional view illustrating one embodiment of an electrostatic chuck;

FIG. 2 is a schematic plan view of the electrostatic chuck illustrated in FIG. 1;

FIG. 3 is a table illustrating the content percentage, the relative density, and the volume resistivity of samples;

FIG. 4 is a schematic cross-sectional view illustrating the operation of the electrostatic chuck;

FIG. 5 is a schematic cross-sectional view illustrating a modified example of an electrostatic chuck;

FIG. 6 is a schematic cross-sectional view illustrating another modified example of an electrostatic chuck; and

FIG. 7 is a schematic cross-sectional view of a semiconductor manufacturing apparatus.

### DESCRIPTION OF THE EMBODIMENTS

One embodiment will now be described with reference to the accompanying drawings. Elements in the drawings may be partially enlarged for simplicity and clarity and thus have not necessarily been drawn to scale. To facilitate understanding, hatching lines may not be illustrated in the cross-sectional drawings.

[Basic Information]

Prior to the description of the embodiments, the basics of an electrostatic chuck will now be described. As illustrated in FIG. 4, an electrostatic chuck includes a mount base 101 on which a substrate W is mounted. The substrate W is, for example, a silicon wafer. The mount base 101 is heated to, for example, approximately 150° C. An electrostatic electrode 102 is embedded in the mount base 101. The mount base 101 is formed from a ceramic, the main component of which is aluminum oxide (Al₂O₃).

When a positive (+) voltage is applied to the electrostatic electrode 102, the electrostatic electrode 102 is electrified with positive (+) charge. This induces negative (−) charge to the substrate W. Consequently, the substrate W is attracted to the mount base 101 by electrostatic attraction force (Coulomb force). The mount base 101 includes a ceramic portion 103 located between the substrate W and the electrostatic electrode 102. The substrate W, the electrostatic electrode 102, and the ceramic portion 103 function as a capacitor. In this case, the ceramic portion 103 functions as a dielectric layer. The electric properties of the ceramic portion 103, particularly, the volume resistivity of the ceramic portion 103, largely affect the attraction operation and the removal operation of the substrate W.

Electric properties of a typical ceramic are such that an increase in the temperature lowers the volume resistivity. Referring to FIG. 4, the heating of the ceramic portion 103 lowers the volume resistivity of the ceramic portion 103. Thus, the substrate W and the electrostatic electrode 102 are easily electrified. Consequently, the substrate W is attracted to the mount base 101 by a larger electrostatic attraction force. In this case, the dominantly acting attraction force changes in accordance with changes in the volume resistivity. When the volume resistivity is high, Coulomb force becomes dominant. When the volume resistivity is low, Johnsen-Rahbek (JR) force becomes dominant. When JR force is dominant, it is difficult to remove the substrate W immediately after stopping the application of voltage to the electrostatic electrode 102. Thus, whenever processing the substrate W, a certain length of time is required for the attraction force to attenuate after stopping the application of voltage to the electrostatic chuck. This decreases the throughput of the substrate processing.

### Embodiments

One embodiment will now be described. As illustrated in FIG. 1, an electrostatic chuck 1 includes a base plate 10 and a mount base 20, which is located on the base plate 10. The mount base 20 is fixed to an upper surface of the base plate 10 by an adhesive agent of a silicone resin or the like. Alternatively, the mount base 20 may be fastened to the base plate 10 by screws.

The material of the base plate 10 is, for example, a metal such as aluminum or cemented carbide. Alternatively, the material of the base plate 10 may be a combination of such a metal and a ceramic. For example, aluminum or an aluminum alloy is used from the viewpoint of the availability, the processibility, the satisfactory thermal conductivity. An alumite process (insulation layer formation) is performed on the surface of the base plate 10. The base plate 10 may include, for example, a passage for supplying a cooling medium (gas, coolant, etc.) that cools the substrate W, which is mounted on the upper surface of the mount base 20. The substrate W is, for example, a semiconductor wafer.

The mount base 20 includes a base body 21, an electrostatic electrode 22, and a heating element 23. The electrostatic electrode 22 and the heating element 23 are located in the base body 21.

The base body 21 is disc-shaped in conformance with the shape of the substrate W. The base body 21 is formed from a ceramic, the main component of which is aluminum oxide (Al₂O₃). Additionally, the ceramic forming the base body 21 contains yttrium oxide (Y₂O₃), magnesium oxide (MgO), and calcium oxide (CaO). Further, the ceramic may contain other materials, which may be, for example, silicon dioxide (SiO₂).

The mount base 20 is obtained by locating a metal material for the electrostatic electrode 22 and an electrothermal material for the heating element 23 between green sheets in a layered manner and sintering the layered body. The material of the electrostatic electrode 22 and the heating element 23 is, for example, a conductive paste that contains tungsten (W) as a main raw material.

In one embodiment, the electrostatic electrode 22 is of a bipolar type and includes a first electrostatic electrode 22a and a second electrostatic electrode 22b. Instead of the bipolar electrostatic electrode 22, a monopolar electrostatic electrode, which is formed by a single electrostatic electrode, may be used. The electrostatic electrode 22 is a thin film of a conductive element. The electrostatic electrode 22 is formed from, for example, a conductive paste that contains tungsten (W) as a main raw material. Alternatively, the material of the electrostatic electrode 22 may be molybdenum (Mo).

The heating element 23 is located below the first electrostatic electrode 22a and the second electrostatic electrode 22b. The heating element 23 includes heater electrodes that are capable of independently performing heating control on different regions (heater zones) of the base body 21 defined in a plan view (as viewed from upper surface of mount base 20). The heating element 23 may be configured as a single heater electrode. The heating element 23 is a thin film of a conductive element. The heating element 23 is formed from, for example, a conductive paste that contains tungsten (W) as a main raw material. Alternatively, the material of the heating element 23 may be molybdenum (Mo).

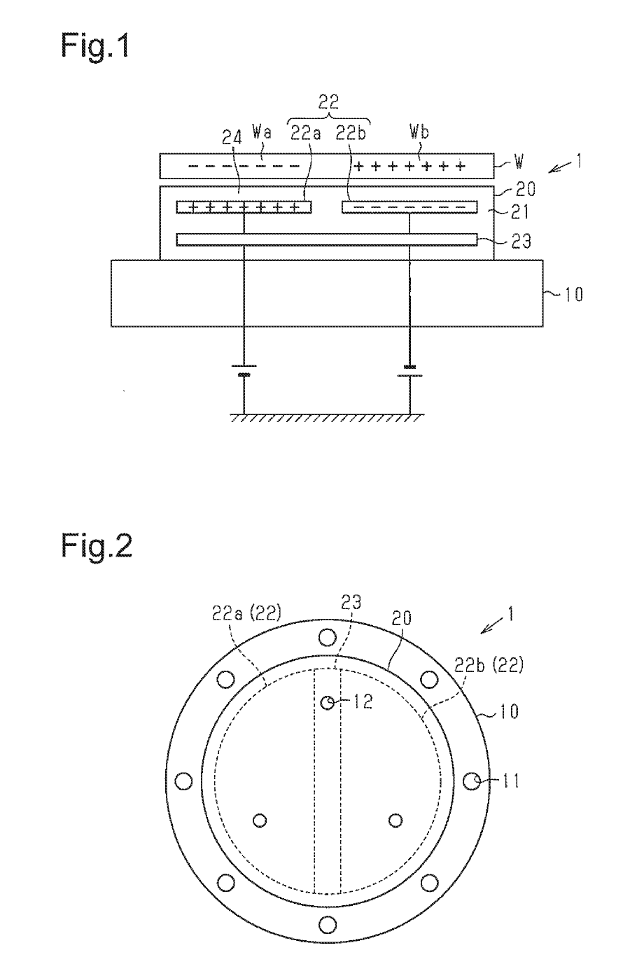

As illustrated in FIG. 2, in the electrostatic chuck 1, the mount base 20 is located on the disc-shaped base plate 10. The base plate 10 includes a circumferential edge, which projects outward from the circumference of the mount base 20. The circumferential edge of the base plate 10 includes coupling holes 11, which are arranged along the circumferential edge to couple the electrostatic chuck 1 to a chamber of the semiconductor manufacturing apparatus. The mount base 20 and the base plate 10 each include a central portion, which includes three lift pin openings 12. The lift pin openings 12 receive lift pins, which move the substrate W upwardly and downwardly. When the lift pins are moved upward, the substrate W is loaded and unloaded between the electrostatic chuck 1 and a transport device.

Additionally, an inert gas may be supplied to the upper side of the mount base 20 through the lift pin openings 12. The inert gas is, for example, helium (He) gas. When the inert gas is supplied between the mount base 20 and the substrate W, heat is efficiently transmitted from the mount base 20 to the substrate W. Gas openings for supplying the inert gas may be arranged separately from the lift pin openings 12.

As illustrated in FIG. 1, in the electrostatic chuck 1, the substrate W is mounted on the mount base 20. The positive (+) voltage is applied to the first electrostatic electrode 22a. The negative (−) voltage is applied to the second electrostatic electrode 22b. This electrifies the first electrostatic electrode 22a with positive (+) charge and the second electrostatic electrode 22b with negative (−) charge. Consequently, negative (−) charge is induced to a portion Wa of the substrate W corresponding to the first electrostatic electrode 22a. Also, positive (+) charge is induced to a portion Wb of the substrate W corresponding to the second electrostatic electrode 22b.

The mount base 20 (base body 21) includes a portion located between the substrate W and the electrostatic electrode 22 defining a ceramic portion 24. The substrate W, the electrostatic electrode 22, and the ceramic portion 24 function as a capacitor. In this case, the ceramic portion 24 functions as a dielectric layer. When voltage is applied to the electrostatic electrode 22, Coulomb force is generated between the electrostatic electrode 22 and the substrate W through the ceramic portion 24 and electrostatically attracts the substrate W to the mount base 20. Additionally, when a given voltage is applied to the heating element 23, the mount base 20 is heated. The temperature of the mount base 20 is controlled to adjust the substrate W to a given temperature. The temperature for heating the electrostatic chuck 1 is set to 100° C. to 200° C. The heating temperature is set to, for example, 150° C.

As described in the basic information, when the ceramic forming an electrostatic chuck is heated, the volume resistivity of the ceramic is largely lowered. In such an electrostatic chuck, the substrate cannot be immediately removed even when voltage application is stopped.

The inventers of this application have found a ceramic material that has the given volume resistivity when the electrostatic chuck 1 is heated to approximately 150° C. For example, when the temperature of the electrostatic chuck 1 is in a range from 0° C. to 150° C. and the volume resistivity of the ceramic is 1E+16Ω cm or greater, the mount base 20 attracts the substrate W with a sufficient attraction force. In this case, the substrate W may also be stably removed from the mount base 20 immediately after stopping the voltage application. When the temperature of the electrostatic chuck 1 is 100° C., it is preferred that the volume resistivity of the ceramic be 1E+17Ω cm or greater. When the temperature of the electrostatic chuck 1 is 150° C., it is preferred that the volume resistivity of the ceramic be 1E+16Ω cm or greater.

The base body 21 of the electrostatic chuck 1 (mount base 20) having the above properties is obtained from a ceramic that contains aluminum oxide, which serves as a main component, calcium oxide (CaO), magnesium oxide (MgO), and yttrium oxide (Y₂O₃) where the content percentage of calcium oxide is set to 0.4 wt % to 0.6 wt %. The content amount is expressed in percentage.

Preferably, the content percentage of magnesium oxide (MgO) is 1.5 wt % to 2.7 wt %, and the content percentage of yttrium oxide (Y₂O₃) is 0.3 wt % to 0.9 wt %. Additionally, it is preferred that the relative density of the ceramic be 92% to 96%. As is known in the art, the relative density is the ratio of a measured density to a theoretical density.

It is preferred that the amount of sodium (Na) contained in aluminum oxide (alumina powder) be at most some tens of ppm. Also, other materials (auxiliary agents) preferably contain a very small amount of sodium. Alkaline ions including sodium adversely affect the insulation properties of ceramics at a significant level.

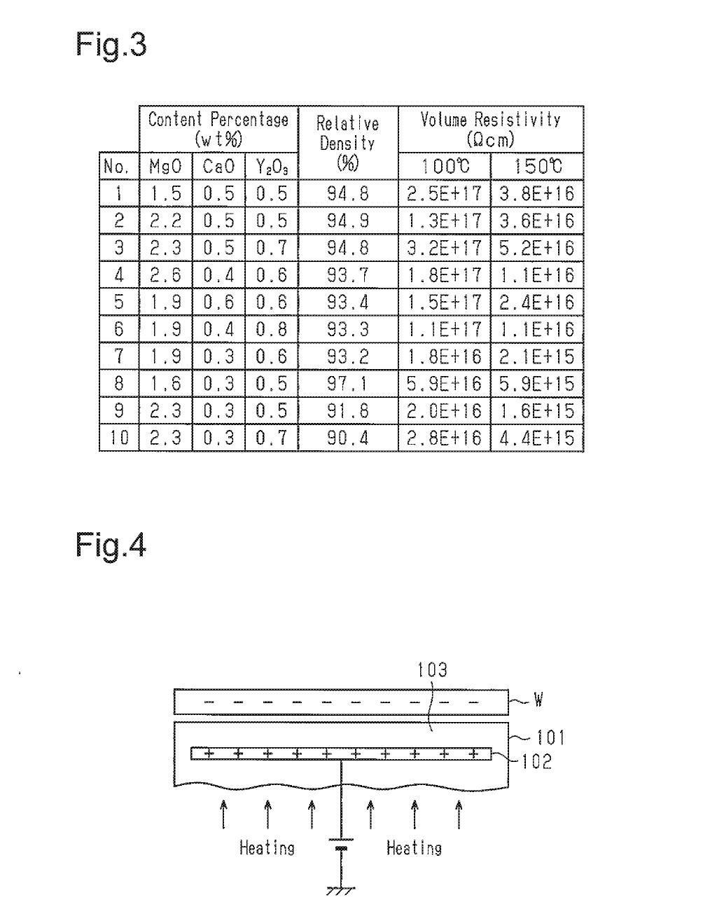

The inventers of this application prepared samples 1 to 10. FIG. 3 illustrates amounts of magnesium oxide, calcium oxide, and yttrium oxide contained in each sample and the relative density and the volume resistivity of each sample.

The samples 1 to 6 each have the preferred composition (content amount) and the preferred relative density, which are described above. In the samples 1 to 6, the content amount of aluminum oxide is 91.7 wt % to 93.9 wt %. The samples 7 to 10 were prepared to compare with the samples 1 to 6. The volume resistivity of each of the samples 1 to 10 was examined. FIG. 3 illustrates the volume resistivity of each of the samples 1 to 10 that was obtained when a given time (e.g., thirty minutes) elapsed from when starting application of a given voltage (e.g., 1000 V) to the electrode of the sample.

As illustrated in FIG. 3, the volume resistivity of each of samples 1 to 6 is 1E+17Ω cm or greater when the sample is heated to 100° C. The volume resistivity of each of samples 1 to 6 is 1E+16Ω cm or greater when the sample is heated to 150° C. When the samples 1 to 10 are heated to 100° C. and 150° C., the volume resistivity of each of the samples 7 to 10is smaller by one digit than samples 1 to 6.

Thus, the ceramic having the above composition and the above relative density has a high volume resistivity (1E+16Ω cm or greater) at 150° C. The mount base 20 formed from a ceramic of such conditions (composition and relative density) allows for quick removal of the substrate W after stopping the voltage application.

The present embodiment has the advantages described below.

(1) The mount base 20 of the electrostatic chuck 1 includes the base body 21 and the electrostatic electrode 22, which is located in the base body 21. The base body 21 is formed from a ceramic that contains aluminum oxide (Al₂O₃), which serves as the main component, magnesium oxide (MgO), yttrium oxide (Y₂O₃), and calcium oxide (CaO). The content percentage of calcium oxide (CaO) is set to 0.4 wt % to 0.6 wt %. The volume resistivity of the ceramic is 1E+16Ω cm or greater at 150° C. In the electrostatic chuck that includes the mount base 20 formed from such a ceramic, Coulomb force dominates the electrostatic attraction force, which attracts the substrate W. This allows for quick removal of the substrate W after stopping voltage application.

(2) The relative density of the ceramic forming the base body 21 is set to 94% to 96%. The volume resistivity varies depending on the relative density of the ceramic. Thus, the relative density is set to the above range so that the mount base 20 has the preferred volume resistivity.

It should be apparent to those skilled in the art that the foregoing embodiments may be employed in many other specific forms without departing from the scope of this disclosure. Particularly, it should be understood that the foregoing embodiments may be employed in the following forms.

In the embodiment, the electrostatic chuck 1 may include any members, which may be located at any positions.

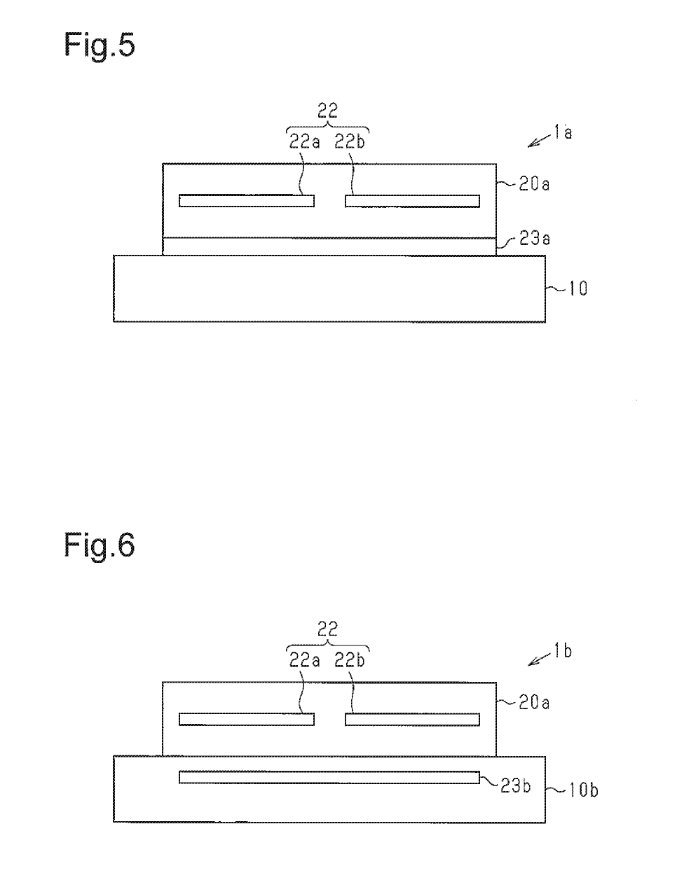

In one example, as illustrated in FIG. 5, an electrostatic chuck 1a includes a heating element 23a that is located between the base plate 10 and a mount base 20a.

In another example, as illustrated in FIG. 6, an electrostatic chuck 1b includes a base plate 10b and a heating element 23b, which is located in the base plate 10b. The mount base 20a is fixed to the base plate 10b.

The heating element may be externally located below the base plate.

The heating element may be omitted from the electrostatic chuck 1. In this case, a manufacturing apparatus may include a heater member, which is formed by a lamp heater or the like and located at a stage in the chamber of the manufacturing apparatus. The electrostatic chuck may be coupled to the stage.

The electrostatic chuck 1 of the embodiment and modified examples may be applied to various kinds of manufacturing apparatuses.

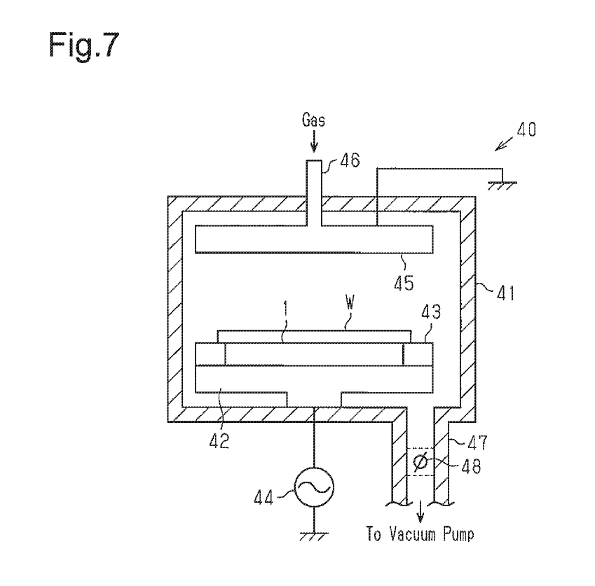

FIG. 7 illustrates an example of a semiconductor manufacturing apparatus 40 that includes the electrostatic chuck 1. The semiconductor manufacturing apparatus 40 is, for example, a dry etching apparatus (e.g., a capacitive coupled plasma reactive ion etching (RIE) apparatus).

The semiconductor manufacturing apparatus 40 includes a chamber 41 and a lower electrode 42, which is accommodated in the chamber 41. The electrostatic chuck 1, which has been described above, is coupled to a surface of the lower electrode 42. The substrate W is mounted on the electrostatic chuck 1. A protective quartz ring 43 extends around the electrostatic chuck 1. A high frequency power supply 44, which supplies RF power, is connected to the lower electrode 42 and the electrostatic chuck 1. The high frequency power supply 44 is connected to a RF matcher (not illustrated), which matches outputs of RF power.

The chamber 41 also accommodates an upper electrode 45, which is an opposing electrode of the lower electrode 42. The upper electrode 45 is connected to ground. The upper electrode 45 is connected to a gas inlet pipe 46, which draws a given etching gas into the chamber 41. The chamber 41 includes a lower wall connected to a vent pipe 47. The vent pipe 47 is coupled to a vacuum pump (not illustrated). Thus, reaction by-products and the like, which are produced through etching, are discharged through the vent pipe 47 to an external device for manufacturing a discharge gas. The vent pipe 47 includes an automatic pressure control valve 48 (APC valve) at a position proximate to the chamber 41. The open degree of the APC valve 48 is automatically adjusted so that the chamber 41 is set to the set pressure.

In the semiconductor manufacturing apparatus 40, the electrostatic chuck 1 is heated by the heating element 23 (refer to FIG. 1) to approximately 150° C. The substrate W is placed on the electrostatic chuck 1. When the voltage of at most ±3000 V is applied to the first electrostatic electrode 22a and the second electrostatic electrode 22b (refer to FIG. 1) of the electrostatic chuck 1, the electrostatic chuck 1 attracts the substrate W. Consequently, the substrate W is heated at the temperature of 150° C.

Then, halogen gas such as chlorine-based gas or fluorine-based gas is drawn into the chamber 41 from the gas inlet pipe 46. The pressure of the chamber 41 is set to the given pressure by the APC valve 48. Additionally, the high frequency power supply 44 applies RF power to the lower electrode 42 and the electrostatic chuck 1 to generate a plasma in the chamber 41.

The application of RF power to the electrostatic chuck 1 forms a negative self-bias in the electrostatic chuck 1. Consequently, positive ions in the plasma are accelerated toward the electrostatic chuck 1. This performs anisotropic etching on an etching subject layer formed on the substrate W to pattern the etching subject layer in a high temperature atmosphere of 150° C. or higher. The etching subject layer to which high temperature etching is applied is, for example, a copper (Cu) layer. Copper chloride, which has a low volatility, tends to be volatile and facilitate the etching in a high temperature atmosphere.

As described above, even when the electrostatic chuck 1 is heated to approximately 150° C., the volume resistivity of the ceramic portion 24 (refer to FIG. 1) is not largely lowered. Thus, the necessary volume resistivity is obtained. When etching is completed, this allows for stable removal of the substrate W from the electrostatic chuck 1 by lifting the lift pins (not illustrated) immediately after stopping application of voltage to the electrostatic chuck 1. In the present embodiment, after stopping the application of voltage to the electrostatic chuck 1, there is no need to wait for a certain length of time until the force attracting the substrate W is attenuated. This increases the throughput in the substrate processing. The present embodiment also limits transport errors caused by displacement or breakage of the substrate W. This increases the throughput yield for manufacturing semiconductor devices.

In FIG. 7, the above embodiment of the electrostatic chuck 1 is applied to the dry etching apparatus. Instead, the electrostatic chuck 1 may be applied to various kinds of manufacturing apparatuses (semiconductor manufacturing apparatuses) such as a plasma chemical vapor deposition (CVD) apparatus or a sputtering apparatus.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to an illustration of the superiority and inferiority of the invention. Although embodiments have been described in detail, it should be understood that various changes, substitutions, and alterations could be made hereto without departing from the scope of this disclosure.

1. An electrostatic chuck comprising:
a mount base including a base body and an electrostatic electrode, wherein
the electrostatic electrode is located in the base body,
the base body is formed from a ceramic that contains aluminum oxide, which serves as a main component, yttrium oxide, magnesium oxide, and calcium oxide, and
a content percentage of the calcium oxide is 0.4 wt % to 0.6 wt %.

2. The electrostatic chuck according to claim 1, wherein the ceramic has a relative density of 92% to 96%.

3. The electrostatic chuck according to claim 1, wherein the base body has a volume resistivity of 1E+16Ω cm or greater in a range from 0° C. to 150° C.

4. The electrostatic chuck according to claim 1, wherein a content percentage of the magnesium oxide is 1.5 wt % to 2.7 wt %.

5. The electrostatic chuck according to claim 1, wherein a content percentage of the yttrium oxide is 0.3 wt % to 0.9 wt %.

6. A semiconductor manufacturing apparatus comprising:
a chamber; and
an electrostatic chuck located in the chamber, wherein
the electrostatic chuck includes a mount base on which a substrate to be processed in the chamber is mounted, wherein
the mount base includes
a base body formed from a ceramic that contains aluminum oxide, which serves as a main component, yttrium oxide, magnesium oxide, and calcium oxide, and
an electrostatic electrode located in the base body, and
a content percentage of the calcium oxide is 0.4 wt % to 0.6 wt %.
